(19) United States
(12) Patent Application Publication
(10) Pub. No.: US 2026/0339217 A1
(43) Pub. Date: Oct. 29, 2026

(54) Ultraviolet Metasurface Projection Optical System

(71) Applicant: Northeast Normal University, Changchun (CN)

(72) Inventors: Zhongzhu LIANG, Changchun (CN); Siyu GUO, Changchun (CN); Shencheng FU, Changchun (CN); Haiyang XU, Changchun (CN); Xiaoyan SHI, Changchun (CN); Fuming YANG, Changchun (CN); Yichun LIU, Changchun (CN)

(21) Appl. No.: 19/331,832

(22) Filed: Sep. 17, 2025

(30) Foreign Application Priority Data
Apr. 27, 2025 (CN) 202510534580.0

(51) Int. Cl. G03F 7/00

(52) U.S. Cl. CPC G03F 7/70316; G03F 7/70225

(57) ABSTRACT

An ultraviolet metasurface projection optical system includes: a point light source for emitting electromagnetic waves; a first metasurface provided on an optical path of the point light source, for regulating phase and amplitude of the electromagnetic waves to obtain parallel light with an expanded spot diameter, and reflecting the parallel light at a preset reflection angle; a mask plate provided on a reflected optical path of the first metasurface; a second metasurface, provided on an optical path of emergent light from the mask plate, for focusing an incident laser; and a photosensitive material provided at a focal position of the second metasurface, for obtaining a reduced pattern on the mask plate.

### CROSS-REFERENCE TO RELATED APPLICATIONS

The present application claims priority to Chinese Patent Application No. 202510534580.0, titled “Ultraviolet Metasurface Projection Optical System”, filed on Apr. 27, 2025, the entire disclosure of which is hereby incorporated herein by reference.

### TECHNICAL FIELD

The present application relates to the field of ultraviolet metasurface projection lithography, and in particular to an ultraviolet metasurface projection optical system.

### BACKGROUND

Ultraviolet lithography is a key technology in microelectronics manufacturing. Its core mechanism is to project fine patterns on the mask onto a silicon wafer coated with photoresist through an optical system by means of ultraviolet light irradiation, causing a photochemical reaction in the photoresist. After subsequent process steps such as development and etching, the pattern is finally transferred to a silicon wafer, thereby constructing precise microscale or even nanoscale structures.

As a strong candidate for the next-generation lithography technology, ultraviolet lithography technology shows broad development prospects. However, as manufacturing processes impose stricter requirements on a feature size of patterns, the demand for higher resolution in lithography technology is also increasing. Against this background, traditional contact and proximity lithography technologies have been difficult to meet production needs and are gradually being replaced by projection lithography technology. The innovation of projection lithography technology lies in the clever introduction of a projection objective lens between the mask and the photoresist. The light first penetrates the mask, then enters the projection objective lens, and finally is focused and imaged on the photoresist by the projection objective lens. This innovative projection exposure method not only significantly improves the resolution of lithography but also effectively avoids the pollution and damage that may be caused by direct contact between the mask and the photoresist.

The projection exposure system is the core component of the ultraviolet lithography system. The design of ultraviolet lithography projection objectives and illumination systems is one of the important contents in the research of ultraviolet lithography technology, and it is of great significance and role in the development of semiconductor manufacturing equipment.

However, traditional ultraviolet projection lithography systems often rely on complex combinations of mirrors and lens barrels, which not only result in cumbersome optical system structures but also make the entire system bulky. How to realize the miniaturization and high efficiency of projection lithography systems has become an important issue that needs to be addressed urgently.

### SUMMARY

The objective of the present application is to provide an ultraviolet metasurface projection optical system, which can achieve miniaturization and high efficiency of the projection lithography system.

To achieve the above objective, the present application provides the following solutions:

An aspect of the present application provides an ultraviolet metasurface projection optical system, which includes: a point light source for emitting electromagnetic waves; a first metasurface, provided on an optical path of the point light source, for regulating phase and amplitude of the electromagnetic waves to obtain parallel light with an expanded spot diameter, and reflecting the parallel light at a preset reflection angle; a mask plate, provided on a reflected optical path of the first metasurface; a second metasurface, provided on an optical path of emergent light from the mask plate, for focusing an incident laser; and a photosensitive material, provided at a focal position of the second metasurface, for obtaining a reduced pattern on the mask plate.

According to the specific embodiments provided by the present application, the present application discloses the following technical effects:

The present application provides an ultraviolet metasurface projection optical system, which includes: a point light source, a first metasurface, a mask plate, a second metasurface, and a photosensitive material. The point light source is used to emit electromagnetic waves; the first metasurface is provided on an optical path of the point light source and is used to regulate the phase and amplitude of the electromagnetic waves to obtain parallel light with an expanded spot diameter, and reflect the parallel light at a preset reflection angle; the mask plate is provided on a reflected optical path of the first metasurface; the second metasurface is provided on an optical path of emergent light from the mask plate and is used to focus an incident laser; the photosensitive material is provided at the focal position of the second metasurface to obtain the reduced pattern on the mask plate. In the present application, the point light source and the first metasurface are used to replace the bulky and complex beam expander lens sets in traditional optical systems, and the beam expansion function can be realized only through the first metasurface. In the present application, only the second metasurface is used to realize the reduced mask imaging on the photosensitive material, which not only significantly reduces the volume and weight of the ultraviolet metasurface projection optical system, but also lowers the manufacturing cost and maintenance difficulty, thereby opening up a new path for the wide application of ultraviolet lithography systems.

### BRIEF DESCRIPTION OF THE DRAWINGS

To more clearly illustrate the technical solutions in the embodiments of the present application or in the related art, the accompanying drawings required in the embodiments will be briefly introduced below. Obviously, the drawings described below are only some embodiments of the present application. For those skilled in the art, other drawings can also be obtained based on these drawings without exerting creative labor.

FIG. 1 is a light path diagram of a micro ultraviolet metasurface projection lithography system realized by using metasurfaces according to the present application.

FIG. 2 is a schematic diagram of a light field where a divergent light beam is converted into parallel light for emission after an action of the metasurface according to the present application.

FIG. 3 is a schematic diagram of the metasurface capable of focusing an object light beam according to the present application.

FIG. 4 is a schematic diagram of different unit structures according to the present application.

### DETAILED DESCRIPTION OF THE EMBODIMENTS

The technical solutions in the embodiments of the present application will be clearly and completely described below in conjunction with the accompanying drawings in the embodiments of the present application. Obviously, the described embodiments are only a part of the embodiments of the present application, rather than all the embodiments. Based on the embodiments of the present application, all other embodiments obtained by those skilled in the art without creative work shall fall within the protection scope of the present application.

The emergence of metasurface technology provides unprecedented possibilities for simplifying the structure of optical systems and realizing system miniaturization. Metasurfaces can flexibly regulate the amplitude, phase, and polarization characteristics of light at the subwavelength scale, which makes them a key to solving the problem of miniaturizing projection lithography systems. Therefore, in-depth exploration and full utilization of metasurface technology to realize the miniaturization and high efficiency of projection lithography systems have become an important issue that needs to be addressed urgently.

The objective of the present application is to provide an ultraviolet metasurface projection optical system, aiming to realize the miniaturization and high efficiency of the projection lithography system.

Ultraviolet lithography is an important microelectronics manufacturing technology. Its principle is to use ultraviolet light to transfer the pattern of photosensitive materials to a silicon wafer, forming microscale and nanoscale structures.

In order to make the above objectives, features, and advantages of the present application more obvious and understandable, the present application will be further described in detail below with reference to the accompanying drawings and specific implementations.

### Example 1

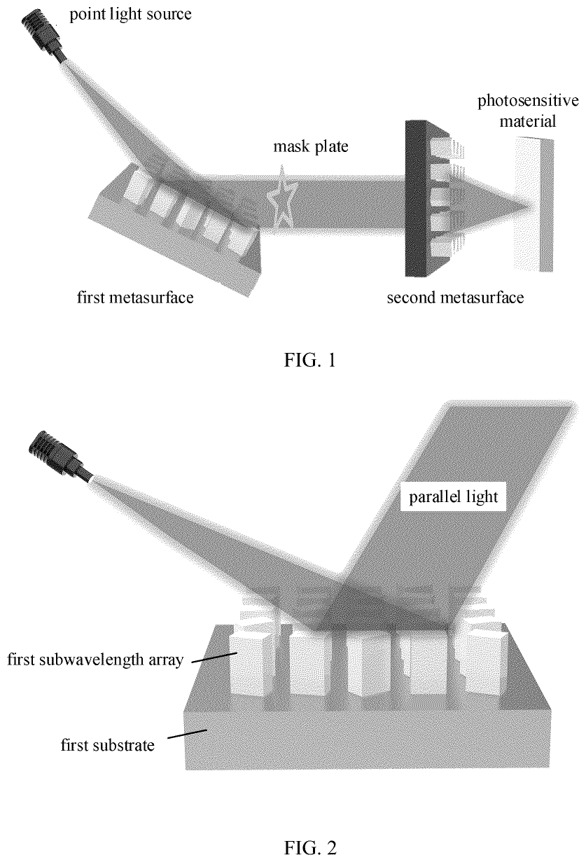

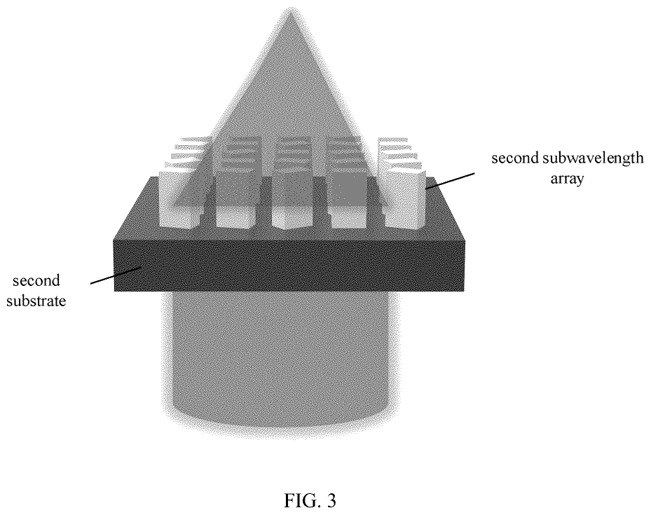

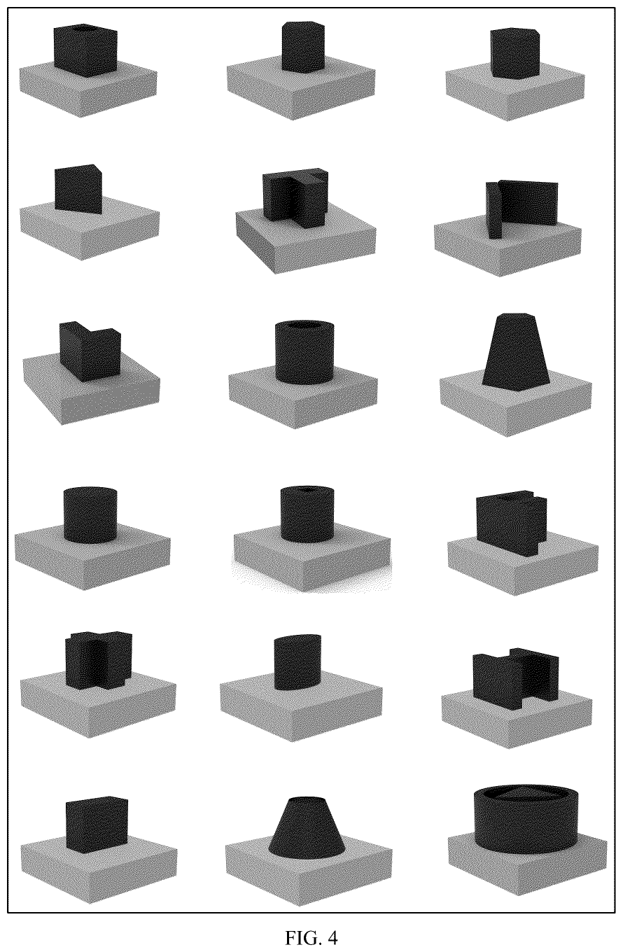

As shown in FIGS. 1 to 4, an ultraviolet metasurface projection optical system in this embodiment includes: a point light source for emitting electromagnetic waves; a first metasurface provided on an optical path of the point light source, for regulating phase and amplitude of the electromagnetic waves to obtain parallel light with an expanded spot diameter, and reflecting the parallel light at a preset reflection angle; a mask plate, provided on a reflected optical path of the first metasurface; a second metasurface provided on an optical path of emergent light from the mask plate, for focusing an incident laser; and a photosensitive material provided at a focal position of the second metasurface, for obtaining a reduced pattern on the mask plat.

According to an embodiment of the present application, the first metasurface includes a first substrate and a first subwavelength array provided on the first substrate; the material of the first substrate is a material with a reflectivity greater than a first preset reflectivity of a ultraviolet band, for example, the first preset reflectivity is set to 70%. The material of the first subwavelength array is a material with a transmittance greater than a first preset transmittance of the ultraviolet band, for example, the first preset transmittance is set to 70%. On this basis, the refractive index of the first subwavelength array is greater than that of the first substrate.

The first substrate is a high-reflection substrate. The first subwavelength array is a rectangular column or elliptical column array with birefringent effect. The material of the first subwavelength array can be one of Nb₂O₅, HfO₂, Ta₂O₅, SiO₂, MgF₂, MgO, Y₂O₃, sapphire, AlN, PMMA, and PS.

According to an embodiment of the present application, the second metasurface includes a second substrate and a second subwavelength array provided on the second substrate; the material of the second substrate is a material with a transmittance greater than a second preset transmittance of the ultraviolet band; the material of the second subwavelength array is a material with a transmittance greater than a first preset transmittance of the ultraviolet band.

The second substrate is a high-transmittance substrate. A high-transmittance substrate results in less loss of electromagnetic waves in the substrate material, and relatively, the transmittance will be relatively higher. It can be considered that within the ultraviolet working bandwidth, the transmittance of the material of the second substrate is greater than 70%. The second subwavelength array is a polarization-insensitive cylindrical array, a rectangular column array with birefringent effect, or an elliptical column array with birefringent effect. The material of the second subwavelength array includes Nb₂O₅, HfO₂, Ta₂O₅, SiO₂, MgF₂, MgO, Y₂O₃, sapphire, AlN, PMMA, PS, etc., one of which can be selected as the material of the second subwavelength array; the refractive index of the material of the second subwavelength array is greater than that of the material of the second substrate.

According to an embodiment of the present application, the wavelength range of the point light source is 10 nm-380 nm.

In practical applications, when the electromagnetic wave emitted by the point light source reaches the first metasurface, the first metasurface uses its subwavelength structure to finely regulate the phase and amplitude of the incident divergent object beam wavefront. This process involves reshaping the electromagnetic wavefront, so that it is directionally reflected at a preset reflection angle. After precise regulation by the first metasurface, the originally divergent light beam is converted into parallel light with an expanded spot diameter. This conversion process reflects the excellent ability of the metasurface to manipulate the electromagnetic wavefront.

In the optical path behind the first metasurface, a mask plate matching the expanded spot diameter is placed. The mask plate carries specific pattern information, which is set according to actual needs. When the object beam carrying this information continues to travel, it will undergo further focusing processing by the second metasurface. The second metasurface regulates the phase of the incident electromagnetic wave with its unique subwavelength structure, achieving the focusing effect on the light beam.

The photosensitive material is precisely placed near a focal position of the second metasurface to ensure that the focused light beam can achieve reduced imaging of the pattern here. This process utilizes the basic principles of optical imaging, and realizes precise control of the pattern size by adjusting the focal length and magnification of the imaging system.

The first metasurface proposed by the present application not only has the ability to reflect the divergent light beam from one side to the other side as parallel light, but also obtains parallel light with an expanded beam diameter in the overall process. This characteristic is intuitively reflected in the schematic diagram of the first metasurface shown in FIG. 1, the first metasurface finely regulates the incident electromagnetic wavefront through additional phase and amplitude information.

FIG. 2 further shows a schematic diagram of the second metasurface in this embodiment that can focus the expanded object beam. By precisely designing the subwavelength structure of the metasurface, fine regulation of the electromagnetic wavefront is realized, thereby realizing the focusing and imaging functions of the light beam.

The first metasurface is composed of a first substrate and a first subwavelength array. The second metasurface is composed of a second substrate and a second subwavelength array.

As a specific implementation, the materials of the second substrate, the first subwavelength array, and the second subwavelength array are all high-transmittance materials of the ultraviolet band. The high-transmittance material can be Nb₂O₅, HfO₂, Ta₂O₅, SiO₂, MgF₂, MgO, Y₂O₃, sapphire, AlN, PMMA, PS, etc. The materials of the second substrate, the first subwavelength array, and the second subwavelength array can be selected from high-transmittance materials, which can be the same or different. For example, to ensure the regulation of electromagnetic waves, the material of the second substrate can be SiO₂, the material of the first subwavelength array can be sapphire, and the material of the second subwavelength array can be Ta₂O₅.

The material of the first substrate in the first metasurface is a material with high reflectivity of a ultraviolet band, such as Ag, Al, Ti, Co, Ni, etc.

In practical applications, the first substrate is a high-reflection substrate. A high-reflection substrate can be considered as having a reflectivity greater than 70%, that is, the reflected electromagnetic wave accounts for 70% of the incident electromagnetic wave. The first subwavelength arrays are all rectangular column or elliptical column arrays with birefringent effect.

The second substrate is a high-transmittance substrate. The second subwavelength array can be a polarization-insensitive cylindrical array, a rectangular column array with birefringent effect, or an elliptical column array with birefringent effect.

The length and width of each unit structure in the first subwavelength array and the second subwavelength array are smaller than a working wavelength, the working wavelength is a working wavelength of the ultraviolet metasurface projection optical system during current operation. A wavelength range of the point light source is the ultraviolet band (10 nm-380 nm).

The present application aims to address the complexity challenges faced by current micro ultraviolet metasurface projection lithography systems. Through innovative design ideas, a micro ultraviolet metasurface projection lithography system scheme is proposed. The core of this scheme lies in cleverly utilizing the precise and efficient regulation ability of metasurfaces on the electromagnetic properties of light waves, thereby highly integrating functions and significantly simplifying the system structure. Specifically, the present application draws on the advanced design concept of Huygens electromagnetic metasurfaces and selects dielectric artificial atoms with flexible phase regulation as the basic units for constructing metasurfaces. These carefully designed unit structures not only ensure the effective transmission of light waves but also provide the possibility of realizing complex optical functions. In the embodiment of the present application, the point light source and the first metasurface are used to replace the bulky and complex beam expander sets in traditional optical systems, and the beam expansion function can be realized only through the first metasurface. In the present application, only the second metasurface is used to realize reduced mask imaging on the photosensitive material. This innovation not only significantly reduces the volume and weight of the system but also lowers the manufacturing cost and maintenance difficulty, opening up a new path for the wide application of ultraviolet lithography systems.

As shown in FIG. 1, the light beam emitted by the point light source shows a tendency to diverge gradually. The first metasurface at a certain distance from the point light source modulates the wavefront of the light and finally emits it as parallel light. This process cleverly uses the point light source and the first metasurface to modulate the light wavefront to realize the expansion of the parallel light spot diameter. Subsequently, this parallel light is projected onto the mask, and after the patterning process of the mask, a light beam with specific information is formed. Then, this light beam passes through the second metasurface, and after its precise focusing and imaging, the pattern is finally mapped on the photosensitive material in a reduced form.

It is worth noting that since the final pattern obtained on the photoresist is the image formed by the lens, the scaling of the pattern can be realized by adjusting the magnification of the projection metasurface lens. This feature allows the selection of a mask with a size larger than the size of the desired pattern when making the mask, reducing the difficulty and error in mask making due to the too small pattern size. And this feature also realizes the multiple use of the same mask, further saving costs.

The present application can realize the parallel reflection and beam expansion effect of divergent light beams with only the first metasurface, which greatly simplifies the traditional beam expansion device. The present application also uses the second metasurface to realize the reduction of the light beam and the scaling of the image with corresponding magnification, further improving the flexibility and practicability of the system.

By virtue of the fine design of the metasurface structure and its excellent ability in wavefront regulation, the present application cleverly replaces the complex beam expander with a mirror. And the second metasurface is used to realize the focusing and imaging of the object beam with corresponding magnification. This greatly simplifies the structure of the system and significantly reduces its volume, injecting new vitality into the development of ultraviolet lithography technology.

The core of the present application lies in the clever application of metasurface technology to realize the simplification and high efficiency of beam processing and regulation. The first metasurface proposed by the present application can precisely regulate the wavefront of the divergent light beam, so that the light beam can be expanded and emitted as parallel light. The second metasurface can accurately focus the light beam on the target position, providing stable energy input for the lithography process. The unique feature of the present application is that parallel light with an expanded spot diameter is obtained by using the point light source and the first metasurface, which effectively reduces the processing difficulty and error of the mask size and improves the precision and reliability of lithography. And the reduced imaging of the mask through the second metasurface further enhances the flexibility and applicability of the system, enabling the system to be applied in a wider range of fields.

The technical features of the above embodiments can be combined arbitrarily. For the sake of concise description, not all possible combinations of the technical features in the above embodiments are described. However, as long as there is no contradiction in the combination of these technical features, they should be regarded as the scope described in this specification.

Herein, specific examples are used to illustrate the principles and implementations of the present application. The description of the above embodiments is only used to help understand the method and core idea of the present application; at the same time, for those skilled in the art, according to the idea of the present application, there will be changes in the specific implementation and application scope. In conclusion, the content of this specification should not be understood as a limitation to the present application.

1. An ultraviolet metasurface projection optical system, comprising:
a point light source for emitting electromagnetic waves;
a first metasurface, provided on an optical path of the point light source, for regulating phase and amplitude of the electromagnetic waves to obtain parallel light with an expanded spot diameter, and reflecting the parallel light at a preset reflection angle;
a mask plate, provided on a reflected optical path of the first metasurface;
a second metasurface, provided on an optical path of emergent light from the mask plate, for focusing an incident laser; and
a photosensitive material, provided at a focal position of the second metasurface, for obtaining a reduced pattern on the mask plate.

2. The ultraviolet metasurface projection optical system according to claim 1, wherein the first metasurface comprises a first substrate and a first subwavelength array provided on the first substrate;
the first substrate is made of a material with a reflectivity greater than a first preset reflectivity of an ultraviolet band; and
the first subwavelength array is made of a material with a transmittance greater than a first preset transmittance of the ultraviolet band; and
a reflectivity of the first subwavelength array is greater than that of the first substrate.

3. The ultraviolet metasurface projection optical system according to claim 2, wherein the first substrate is made of a metal material comprising at least one of Ag, Al, Ti, Co and Ni.

4. The ultraviolet metasurface projection optical system according to claim 2, wherein the first subwavelength array is a rectangular column or elliptical column array with birefringent effect.

5. The ultraviolet metasurface projection optical system according to claim 2, wherein the first subwavelength array is made of a dielectric material comprising at least one of Nb₂O₅, HfO₂, Ta₂O₅, SiO₂, MgF₂, MgO, Y₂O₃, sapphire, AlN, PMMA and PS.

6. The ultraviolet metasurface projection optical system according to claim 2, wherein the second metasurface comprises a second substrate and a second subwavelength array provided on the second substrate;
the second substrate is made of a material with a transmittance greater than a second preset transmittance of the ultraviolet band; and
the second subwavelength array is made of a material with a transmittance greater than the first preset transmittance of the ultraviolet band.

7. The ultraviolet metasurface projection optical system according to claim 6, wherein the second subwavelength array is a polarization-insensitive cylindrical array, a rectangular column array with birefringent effect or an elliptical column array with birefringent effect.

8. The ultraviolet metasurface projection optical system according to claim 6, wherein the material of the second subwavelength array comprises at least one of Nb₂O₅, HfO₂, Ta₂O₅, SiO₂, MgF₂, MgO, Y₂O₃, sapphire, AlN, PMMA and PS; wherein a reflectivity of the material of the second subwavelength array is greater than that of the material of the second substrate.

9. The ultraviolet metasurface projection optical system according to claim 6, wherein the material of the second substrate comprises at least one of Nb₂O₅, HfO₂, Ta₂O₅, SiO₂, MgF₂, MgO, Y₂O₃, sapphire, AlN, PMMA and PS.

10. The ultraviolet metasurface projection optical system according to claim 1, wherein a wavelength range of the point light source is 10 nm-380 nm.
